(19) United States
(12) Patent Application Publication
(10) Pub. No.: US 2004/0222375 A1
(43) Pub. Date: Nov. 11, 2004

(54) Method of determining the concavity and convexity on sample surface, and charged particle beam apparatus

(76) Inventors: Yoshihiro Kimura, Hitachinaka (JP); Osamu Komuro, Hitachinaka (JP); Fumihiro Sasajima, Hitachinaka (JP)

Correspondence Address: DICKSTEIN SHAPIRO MORIN & OSHINSKY LLP, 2101 L STREET NW, WASHINGTON, DC, 20037-1526, US

(21) Appl. No.: 10/779,749

(22) Filed: Feb. 18, 2004

(30) Foreign Application Priority Data
Feb. 19, 2003 (JP) 2003-040494

(51) Int. Cl. G01N 23/225; H01J 37/28

(52) U.S. Cl. 250/310; 250/307

(57) ABSTRACT

A method and apparatus suitable for determining the concavity and convexity of line and space patterns formed on a sample. A profile is formed based on a charged-particle beam scan, the profile having a peak. When one foot portion of the peak converges more gradually than the other foot portion, a portion of the sample corresponding to the one foot portion is determined to be a convex portion. Alternatively, when one foot portion of the peak converges more steeply than the other foot portion, a portion of the sample corresponding to the one foot portion is determined to be a concave portion.

### BACKGROUND OF THE INVENTION

1. Technical Field

The present invention relates to a method of determining the concavity and convexity on a pattern, and more particularly to a method and apparatus suitable for obtaining information about the concavity and convexity on line and space patterns formed on a semiconductor wafer.

2. Background Art

Charged particle beam apparatuses, such as the scanning electron microscope, are suitable for the measurement or observation of the increasingly finer patterns formed on semiconductor wafers. As a method of obtaining three-dimensional information about a sample, particularly information about its the surface concavities and convexities, using a charged particle beam apparatus, a stereoscopic observation method is known, as disclosed in JP Patent Publication (Kokai) No. 5-41195.

In the stereoscopic observation method, a sample is irradiated with beams from two directions inclined with respect to the sample to generate two images. A stereo matching is then performed between the two images to determine corresponding points and calculate heights, thereby obtaining three-dimensional information.

JP Patent Publication (Kokai) No. 5-175496 discloses a technique for measuring pattern sizes by irradiating a pattern on a sample with a beam diagonally.

### SUMMARY OF THE INVENTION

When a line or space pattern on a sample is measured by a scanning electron microscope, if lines and spaces have similar widths, it could be difficult to distinguish between them and the target location for measurement could be mistaken. Particularly, if the contrast between lines and spaces is low, the problem becomes pronounced.

While it is possible to obtain three-dimensional information by irradiating the sample surface with beams diagonally, as disclosed in the above publications, it is necessary in this case to align fields of view after beam inclination. As a result, the processing time for beam inclination increases and the throughput decreases.

It is therefore the object of the invention to provide a method and apparatus for determining the concavity and convexity on patterns, particularly those of lines and spaces, formed on a sample, in a simple manner.

In order to achieve the aforementioned object, in accordance with the invention, a profile is formed based on a charged-particle beam scan, the profile having a peak. When one foot portion of the peak converges more gradually than the other foot portion thereof, a portion of the sample corresponding to the one foot portion is determined to be a convex portion. Alternatively, when one foot portion of the peak converges more steeply than the other foot portion thereof, a portion of the sample corresponding to the one foot portion is determined to be a concave portion.

In this configuration, the concave and convex portions of a concave-convex pattern can be easily determined without inclining the beam.

### BRIEF DESCRIPTION OF THE DRAWINGS

FIG. 1 shows an example of the result of a surface concavity/convexity determination.

FIG. 2 shows a schematic diagram of a scanning electron microscope according to an embodiment of the invention.

FIG. 3 shows observed images of a line pattern and its profile.

FIG. 4 shows an edge profile and its differentiated profile.

FIG. 5 shows a flowchart of an automated inspection procedure based on a concavity/convexity determination.

### DETAILED DESCRIPTION OF THE PREFERRED EMBODIMENTS

Hereafter the method and apparatus for determining the concavity and convexity on a surface according to an embodiment of the invention will be described. In accordance with this embodiment, a conventional substrate is irradiated with a charged particle beam that is incident on the substrate in a perpendicular direction. A charged particle emitted from a scanned location is detected, and a profile of the intensity of the charged particle is drawn. Based on this profile, the convexity and concavity of the substrate surface are determined, without inclining the incident charged particle or the stage carrying the substrate by any optical or mechanical means.

In accordance with this embodiment, surface concavity and convexity within a charged particle beam can be easily determined, and surface concavity and convexity can be easily determined in patterns consisting of similar, successive patterns of lines and spaces.

Since there is no need to carry out either optical or mechanical operations for inclining the incident charged particle or the substrate-supporting stage, the throughput is hardly affected. This is an advantage in automated production processes where emphasis is put on the throughput.

While the following descriptions concern a scanning electron microscope using an electron beam as an example of the charged particle beam apparatus, this is merely exemplary. For example, an ion beam irradiation apparatus using an ion beam may be used.

The perpendicular direction herein refers to the direction identical to the direction in which the charged particle not subjected to deflection is irradiated in the charged particle optical system, or the direction perpendicular to that in which the sample stage is moved when transporting the sample in an X-Y direction. It should be noted, however, that the charged particle beam apparatus is a device for scanning a charged particle beam one or two dimensionally, and deflections for these purposes are not meant when references are made to “inclined irradiation” in the description of the embodiment.

Specifically, in the present embodiment, a charged particle beam shone along its optical axis (the trajectory of the charged particle beam not subjected to deflection by a deflector) is scanned by a scan deflector one or two dimensionally. In other words, the charged particle beam is shone without being deflected by any other deflectors (such that the beam is vertically incident).

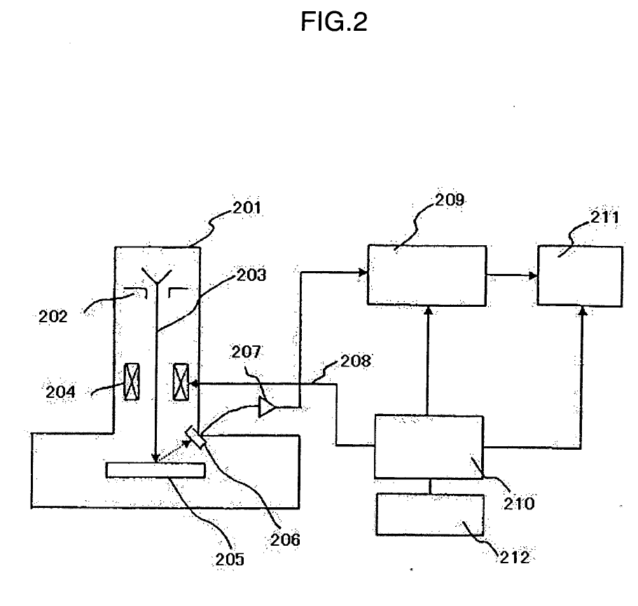

FIG. 2 shows a block diagram of the scanning electron microscope apparatus according to the embodiment. Numeral 201 designates a mirror portion of the electron microscope. An electron beam 203 emitted by an electron gun 202 is converged by an electron lens (not shown) and shone on a sample 205. This electron beam irradiation causes secondary or reflected electrons to be emitted from the sample surface, the intensity of which is detected by an electron detector 206 and amplified by an amplifier 207.

Numeral 204 designates a deflector for moving the position of the electron beam. Based on a control signal 208 from a control computer 210 (also referred to herein as a control processor or a control system), the deflector 204 causes the electron beam to raster-scan the surface of the sample. A signal outputted from the amplifier 207 is A-D converted in an image processor 209 to generate digital image data, based on which a profile is created by a projection processing.

Numeral 211 designates a display apparatus for displaying the aforementioned image data. The image processor 209 includes an image memory for storing the digital image data and carries out various image processes. It also includes a display control circuit for display control. Input means 212, such as a keyboard and mouse, is connected to the control computer 210.

The scanning electron microscope is used for measuring the line width of the fine patterns formed on a wafer during the production of a semiconductor device. When a line or space is measured to determine the line width of the wafer, if the lines and spaces have similar widths, they cannot be distinguished based on their width information. In such a case, they must be distinguished based on surface concavity/convexity information.

An address signal corresponding to an image memory position is generated in the control computer 210, analog-converted and then supplied to the deflector 204 via a scan-coil control power supply (not shown). An X-direction address signal is a digital signal that, in the case of 512×512 pixels in the image memory, repeats 0 to 512. A Y-direction address signal is a digital signal that repeats 0 to 212 such that 1 is added when the X-direction address signal reaches from 0 to 512. These digital signals are converted into analog signals.

Because the address in the image memory correspond to the address of the deflecting signal for scanning the electron beam, a two-dimensional image of the region in which the electron beam is deflected by the deflector 204 is recorded in the image memory. Signals in the image memory can be read out sequentially in a chronological order with a read-address generating circuit (not shown) synchronized with a read clock. The signals read from individual addresses are analog-converted into intensity modulation signals for the display apparatus 211.

The image memory is equipped with the function of storing images (image data) in a superposed (composed) manner for S/N improvement purposes. For example, by storing images obtained in eight two-dimensional scans in a superposed manner, a single complete image can be formed. Thus, a final image can be formed by composing images formed by one or more X-Y scans. The number of images (the number of accumulated frames) for forming a single complete image can be set to an appropriate value as necessary, in light of the secondary electron generation efficiency or other conditions. It is also possible to superpose a plurality of images formed by accumulating multiple images to form a final image. When or after a desired number of images are stored, a blanking of the primary electron beam can be performed in order to interrupt the feeding of information into the image memory.

The sample 205 is placed on a stage (not shown) and can be moved in two directions (X and Y) in a plane perpendicular to the electron beam.

The apparatus according to the embodiment is also equipped with a function for forming a line profile based on the detection of secondary electrons or reflected electrons. The line profile is formed, e.g., on the basis of the amount of electrons detected upon one- or two-dimensional scan of the primary electron beam, or based on the brightness information about the sample image. The resultant profile is used for measuring the size of a pattern formed on the semiconductor wafer, for example. The apparatus of the embodiment further has the functions for forming a differentiated waveform based on the obtained line profile and for calculating the distance between a peak position and a predetermined height of the profile waveform.

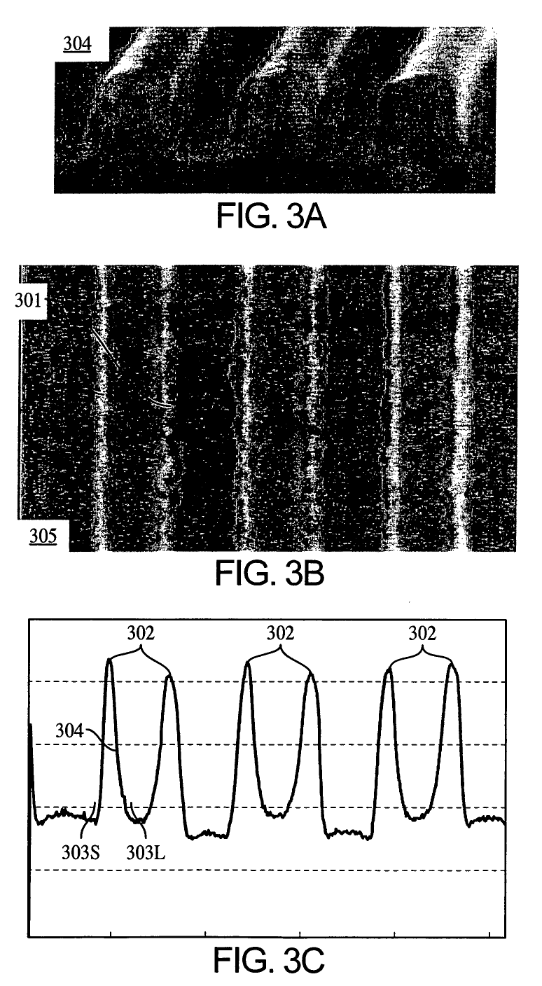

While FIG. 3 has been described on the assumption that the control computer is part of or effectively part of the scanning electron microscope, this is merely exemplary. For example, a control processor may be provided separate from the scanning electron microscope to perform processes as described below. In this case, there must be provided a transmitting medium for transmitting detection signals detected by a secondary signal detector 313 to the control processor and for transmitting a signal from the control processor to the lenses or deflector in the scanning electron microscope, and an input/output terminal for the input and output of the signals transmitted via the transmitting medium.

Alternatively, a program for carrying out the processes described below may be registered in a storage medium, and the program may be run by a control processor equipped with an image memory and adapted to supply signals required by the scanning electron microscope.

FIG. 3 shows line and space images and an edge profile peak portion of these images. Numeral 304 designates a cross section and 305 designates a plan view. The images and profiles of the embodiment are all so-called top-down images where the conventionally used charged particle is incident on the sample perpendicularly.

In the profile of FIG. 3, the boundaries between the lines and spaces in image 304 appear as portions 301 with high secondary electron intensities in image 305, and they form peaks 302 in the profile data. When attention is focused on the foot of the peak 302, and the shapes of a foot portion 303L towards the line and a foot portion 303S towards the space are compared, it is seen that the foot portion 303L towards the line tends to transitions to the base of the profile at a slower rate, due to the influence of the secondary electrons or reflected electrons from the edge side walls.

Thus, the peak shapes are asymmetric about their respective peak vertexes. The profile waveforms of the line (convex) portions converge more gradually at the foot portion than the profile waveforms of the space (concave) portions. Conversely, the foot portions of the space profile waveforms converge more steeply than the foot portions of the line profile waveforms. In the present embodiment, the surface concavity and convexity on the sample are determined based on this principle.

The peaks 302 of the profile are determined based on a threshold determined on the basis of the profile of FIG. 3 in advance, and a surface concavity/convexity determination is carried out on each of the thus determined peaks.

The method of determining sample surface concavity and convexity will be hereafter described in concrete terms. While in the following descriptions the concavity/convexity determination is conducted with the use of a differentiated waveform suitable for quantitative analysis of the profile waveform, this is merely exemplary. Thus, any other means may be employed as long as they are capable of determining surface concavity and convexity based on the width of the foot portion of the profile waveform with a certain validity.

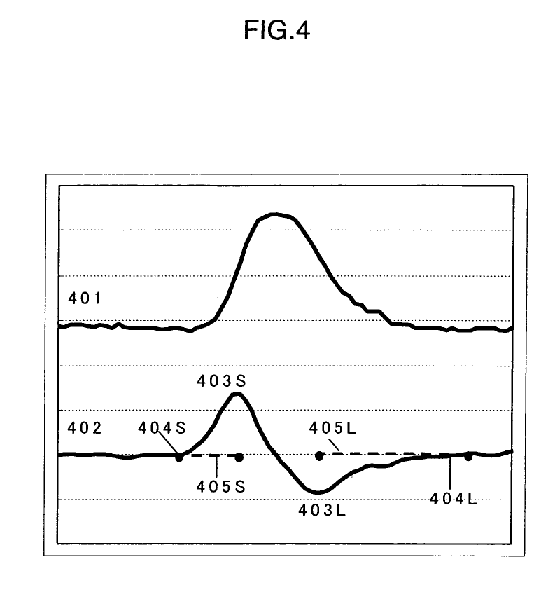

FIG. 4 shows a profile 401 that is an enlargement of one of the profile peaks 304 of FIG. 3, and a profile 402 (to be hereafter referred to as a differentiated profile) obtained by differentiating the profile 401. When attention is focused on the interval between each of a peak position 403S towards the space and a peak position 403L towards the line and a point where their peaks become zero, it will be seen that the peaks are asymmetric between the space and line, and that the degree of this asymmetry is larger than that in the profile. Thus, based on an interval 405S between the space-side peak position 403S and a zero-point 404S and a distance 405L between the line-side peak position 403L and a zero-point 404L, the asymmetry of the differentiated profile can be evaluated, which in turn makes it possible to evaluate the profile.

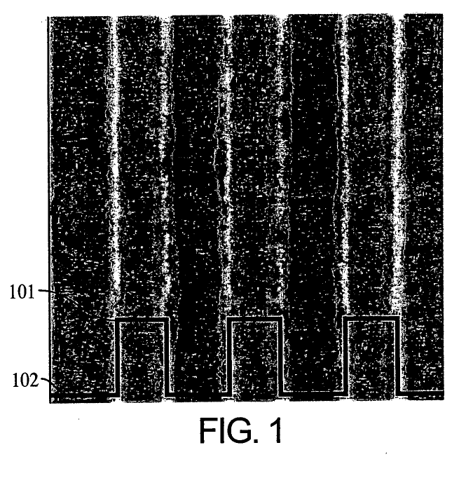

Evaluation values can be calculated for the left and right sides of the center at the peak vertex of the profile, using the intervals 405S and 405L of the differentiated profile of FIG. 4 relative to the respective zero points, and the larger evaluation value (the peak with a wider foot) is determined as corresponding to the line. This can be conducted for all of the peaks of the profile, thus determining the concavities and convexities of the pattern in the image. FIG. 1 shows an SEM image in which the result of the concavity/convexity determination has been incorporated. An upper portion 101 of the rectangular line at the bottom of the image corresponds to a line (convex) portion, while a lower portion 102 corresponds to a space (concave) portion. This line exists only in terms of image processing and does not indicate any changes imparted to the object under investigation. By comparing with the image 304 of FIG. 3, it will be seen that the determination has been correctly done.

Thus, in accordance with the above-described embodiment, the surface concavity and convexity of the sample can be determined without employing complex image processing techniques. Further, the concavity/convexity determination can be conducted by a method involving the formation of a line profile, which is simpler than image processing, the method of the invention can be easily incorporated into the automatic measurement function of semiconductor inspection apparatus, while minimizing the influence of such incorporation on the throughput.

Particularly, the invention allows the concavity/convexity of patterns consisting of similar patterns such as lines and spaces to be determined easily. The concavity/convexity determination of the invention can be conducted even when the contrast between the lines and spaces is low, and the invention is not subject to the composition forming the lines and spaces.

If the concavity-convexity determination is unsuccessful, it is often difficult to proceed with further measurement. In such a case, an error message may be generated to call attention to the operator. Further, in cases where the sample comprises many measurement or observation points on a single wafer, such as a semiconductor wafer, the measurement or observation of the point of error may be skipped in favor of the next measurement or observation.

Further, a mechanism may be incorporated such that, in addition to the aforementioned error message, another error message is generated for a pattern for which a concavity-convexity determination is possible but the next inspection step, such as the measurement of a line width, could be difficult, based on thresholds such as the number of edges or the evaluation value of the shape of profile.

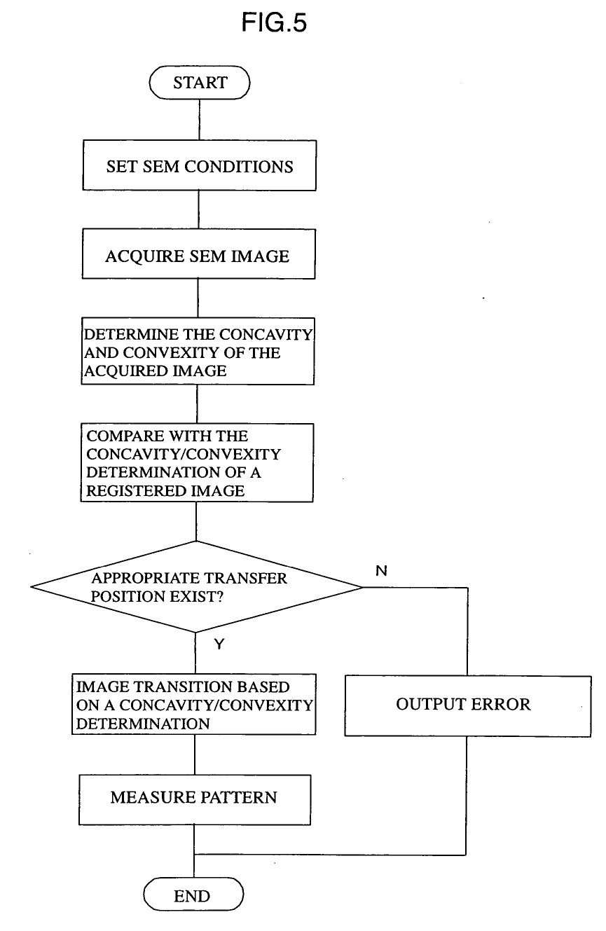

FIG. 5 shows an example of the flow of an automated inspection process. Based on the result of a concavity-convexity determination of a model image that is registered in advance for positioning purposes, and the result of a concavity-convexity determination conducted at a positioned location, the position of the image is fine-adjusted such that the positioned location becomes a set location for measuring the pattern size is measured, and then the size is measured. This method is particularly effective when the size ratio of line and space is close to 1:1 and it is difficult to distinguish lines and spaces based on the size width.

In accordance with the invention, a concavity-convexity determination can be conducted on the surface of a sample without inclining the charged particle beam.

What is claimed is:

1. A method of determining the concavity and convexity on a sample, comprising the steps of scanning a portion of a sample including a convex pattern formed thereon with a charged particle beam, and forming a profile waveform based on a charged particle emitted from a location of said sample that has been scanned, said profile waveform comprising a peak, wherein, when one foot portion of said peak converges more gradually than the other foot portion thereof, a portion of said sample corresponding to said one foot portion is determined to be a convex portion.

2. A method of determining the concavity and convexity on a sample, comprising the steps of scanning a portion of a sample including a concave pattern formed thereon with a charged particle beam, and forming a profile waveform based on a charged particle emitted from a location of said sample that has been scanned, said profile waveform comprising a peak, wherein, when one foot portion of said peak converges more steeply than the other foot portion thereof, a portion of said sample corresponding to said one foot portion is determined to be a concave portion.

3. The method of determining the concavity and convexity on a sample according to claim 1 or 2, wherein the charged particle beam is incident on the plane of a substrate perpendicularly.

4. The method of determining the concavity and convexity on a sample according to claim 3, wherein said profile waveform is created based on a charged particle emitted from a location of said sample that has been scanned as the charged particle beam that is perpendicularly incident on the sample is scanned by a scanning deflector.

5. The pattern position detection method according to claim 1 or 2, wherein the position of a pattern on said sample is identified based on the information about the concave and/or convex portions that have been determined.

6. The pattern position detection method according to claim 1 or 2, wherein a convex-concave pattern formed on a substrate is scanned by a charged particle beam, a profile waveform is created based on a reflected or secondary charged particle emitted from a scanned location, and a specific position of said pattern on said substrate is detected based on pattern convex-concave information obtained by said method of determining the concavity and convexity on a sample.

7. The pattern position detection method according to claim 6, wherein a comparison is made with concavity-convexity information about a pre-registered model, in order to detect a specific position on said pattern on said sample.

8. The pattern position detection method according to claim 6, wherein a comparison is made with the profile shape of a pre-registered model, and an error is detected if an evaluation value indicating the difference in their profile shapes exceeds a predetermined value.

9. The pattern position detection method according to claim 6, wherein a comparison is made with the number of edges in a pre-registered model, and an error is detected if the numbers of edges exceed a predetermined value.

10. A method of determining the concavity and convexity on a sample, comprising the steps of scanning a portion of a sample comprising a convex and/or concave pattern formed thereon with a charged particle beam, forming a profile waveform based on a charged particle emitted from a scanned location, and forming a differentiated waveform of said profile waveform, said differentiated waveform having at least two peaks, wherein a portion of said sample corresponding to a longer interval between the position of one of the peaks and a point where the differentiated waveform becomes zero or converges is determined to be a convex portion, and a portion of said sample corresponding to a shorter interval is determined to be a concave portion.

11. A charged particle beam apparatus comprising a charged particle source, a scanning deflector for scanning a charged particle beam emitted by said charged particle source, and a detector for detecting a charged particle emitted by a sample irradiated by said charged particle beam, wherein the improvement comprises:
a control processor for forming a profile waveform comprising a peak based on the detected charged particle, wherein, when one foot portion of said peak converges more gradually than the other foot portion thereof, a portion of said sample corresponding to said one foot portion is determined by said control processor to be a convex portion.
